(19) United States
(12) Patent Application Publication
(10) Pub. No.: US 2025/0137167 A1
(43) Pub. Date: May 1, 2025

(54) METHODS OF FORMING PEROVSKITE OXIDE MEMBRANES

(71) Applicant: Regents of the University of Minnesota, Minneapolis, MN (US)

(72) Inventors: Bharat Jalan, Minneapolis, MN (US); Shivasheesh Varshney, Minneapolis, MN (US); Sooho Choo, Minneapolis, MN (US)

(21) Appl. No.: 18/935,125

(22) Filed: Nov. 1, 2024

Related U.S. Application Data
(60) Provisional application No. 63/546,838, filed on Nov. 1, 2023.

(51) Int. Cl. C30B 23/02; C30B 29/32

(52) U.S. Cl. CPC C30B 23/02; C30B 23/025; C30B 29/32

(57) ABSTRACT

The present document relates to methods of forming a perovskite oxide, as well as stacks for use in preparing a perovskite oxide. A method of forming a perovskite oxide includes: growing, using molecular beam epitaxy (MBE), a sacrificial layer on a substrate; growing, using MBE, a thin-film on the sacrificial layer to form a stack; and removing the sacrificial layer to detach the thin-film from the stack.

### CROSS-REFERENCE TO RELATED APPLICATION

This application claims priority under 35 U.S.C. § 119 (e) to U.S. Patent Application Ser. No. 63/546,838, filed on Nov. 1, 2023, the entire contents of which are hereby incorporated by reference.

### STATEMENT OF GOVERNMENT SUPPORT

This invention was made with government support under DE-SC0020211 awarded by the U.S. Department of Energy, and FA9550-21-1-0460, and FA9550-21-1-0025 awarded by the Department of the Air Force. The government has certain rights in the invention.

### FIELD

The present document relates to methods of forming free-standing membranes. Compositions and structures including perovskite oxide thin films and alkaline earth metal binary oxide are described herein.

### SUMMARY

The present document relates to methods of forming free-standing membranes using a sacrificial layer. In a first aspect, the present document encompasses a method of forming a perovskite oxide, including: growing, using molecular beam epitaxy (MBE), a sacrificial layer on a substrate; growing, using MBE, a thin-film on the sacrificial layer to form a stack; and removing the sacrificial layer to detach the thin-film from the stack.

In another aspect, the present document encompasses a stack including: a substrate having a top surface and a bottom surface; a sacrificial layer disposed on at least a portion of the top surface of the substrate; and a barrier layer disposed on at least a portion of a top surface of the sacrificial layer. Each of the substrate, the sacrificial layer, and the barrier layer can include cubic symmetry. The barrier layer can include an alkaline earth metal stannate.

Implementations of the above-mentioned methods can include one or more of the following features.

In some implementations, the method further includes after said removing, transferring the thin-film to a host substrate.

In some implementations, the host substrate is flexible.

In some implementations, the host substrate includes Au-coated silicon.

In some implementations, the host substrate includes amorphous glass.

In some implementations, the method further includes, before said removing, attaching the thin-film to a supporting layer.

In some implementations, the supporting layer is attached to a thermal release tape.

In some implementations, a hole extends through the thermal release tape, starting at a bottom surface of the thermal release tape in contact with the supporting layer and ending at a top surface of the thermal release tape.

In some implementations, the method further includes, after the thin-film detaches from the stack, attaching the thin-film to a host substrate; and applying heat to the host substrate to cause the thermal release tape to detach. A same surface, or a portion thereof, of the thin-film can be attached to the host substrate as was in contact with the sacrificial layer.

In some implementations, the method further includes removing (e.g., etching) the supporting layer to expose the thin-film.

In some implementations, the method further includes, before said growing the thin-film, growing a barrier layer, the barrier layer having a different chemical composition compared to the sacrificial layer and the thin-film.

In some implementations, the barrier layer includes an alkaline earth metal stannate.

In some implementations, the method further includes, before said removing, growing a second thin-film on said thin-film, the second thin-film having a different chemical composition compared to said thin-film.

In some implementations, the thin-film includes an ABO₃ perovskite, and the second thin-film includes an oxide or a nitride.

In some implementations, the thin-film includes an ABO₃ perovskite.

In some implementations, the thin-film includes SrTiO₃, and the sacrificial layer includes SrO.

In some implementations, the thin-film is substantially single-crystalline.

In some implementations, the sacrificial layer includes one or more alkaline earth metal binary oxides.

In some implementations, a coordinate system of the sacrificial layer is rotated to at least one of a coordinate system of the substrate and a coordinate system of the thin-film.

In some implementations, said removing includes immersing the stack in a liquid, such that the sacrificial layer dissolves and the thin-film detaches from the stack.

In some implementations, the liquid includes deionized water.

In some implementations, the sacrificial layer does not include aluminum.

In some implementations, the substrate includes Si, LuAlO₃, YAlO₃, SrLaAlO₄, LaAlO₃, NSAT (e.g., (NdAlO₃)ₓ—(SrAl_{1/2}Ta_{1/2}O₃)₁₋ₓ, where x is 0.3 to 0.5), LSAT (LaAlO₃)ₓ—(SrAl_{1/2}Ta_{1/2}O₃)₁₋ₓ, where x is 0.2 to 0.4), NdGaO₃, SrTiO₃, DyScO₃, GdScO₃, MgO, or YSZ (yttria-stabilized zirconia).

In some implementations, the sacrificial layer includes CaO, SrO, BaO, MgO, Ca, Sr, or a combination of any of these.

In some implementations, the barrier layer includes SnO₂, Pt, a ruthenate, an iridate, or XSnO₃, in which X is Be, Mg, Ca, Ba, Sr, Ra, or a combination of any of these.

In some implementations, the stack further includes a thin-film disposed on at least a portion of a top surface of the barrier layer.

In some implementations, the thin-film includes an ABO₃ perovskite or a doped form thereof.

In some implementations, the thin-film includes one or more layers, and WHEREIN at least one layer includes an ABO₃ perovskite.

In some implementations, the one or more layers of the thin-film include a doped layer of the ABO₃ perovskite.

In some implementations, the one or more layers of the thin-film include a binary oxide.

In some implementations, the thin-film is piezoelectric.

In some implementations, the thin-film is ferroelectric.

In some implementations, the thin-film includes ScAlO₃, LuAlO₃, YAlO₃, GdAlO₃, BiAlO₃, CaGeO₃, SmAlO₃, NdAlO₃, NdAlO₃, SmCoO₃, CaMnO₃, BiAlO₃, RuO₂, WO₃, SmCoO₃, SrGeO₃, SrMnO₃, CaTiO₃, CaRuO₃, SrCoO₃, PbTiO₃, CaIrO₃, SrTiO₃, SrRuO₃, CaSnO₃, SrIrO₃, BiFeO₃, KTaO₃, BaTiO₃, SrSnO₃, BaIrO₃, SrZrO₃, BaSnO₃, BaHfO₃, BaZrO₃, TiN, GdPtSb, SnO₂, Ca₃SnO, ZrO₂, Sr₃SnO, HfO₂, or a combination of any of these.

In some implementations, a lattice parameter of the sacrificial layer is in a range of 3.6 Å to about 5.1 Å.

Implementation of the described methods can result in one or more following advantages. For example, synthesis of a freestanding membrane can allow for flexible, e.g., bendable, foldable, stretchable, or a combination thereof, devices that can go can undergo mechanical deformation while maintaining their physical properties. These flexible devices have applications in various fields, such as wearable technology, flexible displays, healthcare, and energy storage. These flexible devices can sustain large stress and offer strong ferroelectric responses.

The sacrificial layer can have a relatively simple chemical composition and growth process compared to previously developed sacrificial layers, such as Sr₃Al₂O₆, SrRuO₃, SrVO₃, YBa₂Cu₃O₇, SrCoO_{2.5}, and La_{X}Sr₁₋ₓMnO₃. Further, the sacrificial layer can exclude aluminum, which can negatively interfere with thin-film growth inside molecular beam epitaxy systems.

Additionally, the described techniques avoid wet-etching of a substrate supporting the thin-film, thereby avoiding high costs and acidic solutions that can damage the thin-film. The described techniques can also avoid dry-etching of the substrate, which can damage the thin-film. Using the sacrificial layer can be cost-effective, as the same growth chamber and substrate can be reused after growing removing the thin-film from the substrate.

Another advantage of the disclosed methods is that while the methods provide new techniques, they do not require changes to or additional equipment for a conventional molecular beam epitaxy system.

### Definitions

As used herein, the term “about” means+/−10% of any recited value. As used herein, this term modifies any recited value, range of values, or endpoints of one or more ranges.

By “micro” is meant having at least one dimension that is less than 1 mm and, optionally, equal to or larger than about 1 μm. For instance and without limitation, a microstructure (e.g., any structure described herein) can have a length, width, height, cross-sectional dimension, circumference, radius (e.g., external or internal radius), or diameter that is equal to or larger than about 1 μm and less than 1 mm.

By “nano” is meant having at least one dimension that is less than 1 μm but equal to or larger than about 0.1 nm. For instance and without limitation, a nanostructure (e.g., any structure described herein) can have a length, width, height, cross-sectional dimension, circumference, radius (e.g., external or internal radius), or diameter that is equal to or larger than about 0.1 nm less than 1 μm.

As used herein, the terms “top,” “bottom,” “upper,” “lower,” “above,” and “below” are used to provide a relative relationship between structures. The use of these terms does not indicate or require that a particular structure must be located at a particular location in the apparatus.

Unless otherwise defined, all technical and scientific terms used herein have the same meaning as commonly understood by one of ordinary skill in the art to which this invention pertains. Although methods and materials similar or equivalent to those described herein can be used to practice the invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1A depicts an example of a stack including a substrate, a sacrificial layer, and a thin-film.

FIG. 1B depicts the stack of FIG. 1A attached to a supporting layer and thermal release tape.

FIG. 1C depicts etching the sacrificial layer of the stack of FIG. 1B.

FIG. 1D depicts various composition options for the substrate, the sacrificial layer, and the thin-film, with lattice parameters plotted along a horizontal axis

FIG. 2A depicts an example of a stack including a barrier layer.

FIG. 2B depicts another example of a stack including a non-limiting BaSnO₃ barrier layer.

FIG. 3A depicts the stack of FIG. 1C adhered to a host substrate.

FIGS. 3B, 3C, and 3D depict an example a process of exposing the thin-film of FIG. 3A.

FIG. 4 depicts an example of a method of forming a freestanding membrane.

FIGS. 5A, 5B, 5C, 5D, 5E, and 6 show experimental results of applying the disclosed techniques to a stack including a LaAlO₃ (LAO) substrate, a SrO sacrificial layer, and a SrTiO₃ (STO) thin-film.

FIGS. 7A and 7B depicts wide-angle x-ray diffraction (XRD) results for the stack of FIGS. 5A, 5B, 5C, 5D, 5E, and 6.

FIGS. 8A-8C and 9A-9B show experimental results of applying the disclosed techniques to a stack including a SrTiO₃ substrate, a BaO sacrificial layer, a BaSnO₃ barrier layer, a first SrTiO₃ (STO) thin-film, and a second La doped SrTiO₃ thin-film.

FIGS. 10A and 10B depict results of applying, according to some embodiments, the disclosed techniques to a stack including a LSAT substrate, a SrO sacrificial layer, and a BaTiO₃ thin-film.

FIGS. 11A and 11B depict piezoresponse force microscopy (PFM) results for a freestanding BaTiO₃ membrane.

FIG. 11C depicts polarization-electric field (P-E) hysteresis loop results for the freestanding BaTiO₃ membrane.

FIG. 11D depicts impedance measurements for the freestanding BaTiO₃ membrane.

### DETAILED DESCRIPTION

The present document describes a method of forming free-standing membranes, such as perovskite oxide membranes, through the use of the sacrificial layer. In some cases, the perovskite oxide has a formula of ABO₃, in which each of A and B is, independently, a cation or a metal (e.g., a metal cation). In some cases, the perovskite oxide can include a doped form thereof (e.g., including a dopant selected from another cation or metal that is different than that present in ABO₃). Non-limiting examples of dopants can include any metal or cation described herein.

Perovskite oxides with a chemical formula of ABO₃ can possess desired properties, such as high dielectric constant, ferroelectricity, and superconductivity. Such properties can be used to develop electronic devices. One consideration in the growth of perovskite oxide thin-films is that films are typically grown on limited substrates that have similar crystal structures and lattice parameters to the film. This limitation can prevent perovskite oxides from being used with other material systems, such as the use of a flexible substrate that in turn can be used in flexible electronics. Various methods to detach a grown film from the substrate and transfer them onto arbitrary substrates have been suggested to integrate perovskite oxides' properties into other materials systems. Non-limiting example of perovskite oxides include a metal titanate, such as strontium titanate (SrTiO₃), barium strontium titanate (BaSrTiO₃), barium titanate (e.g., BaTiO₃), or calcium titanate (e.g., CaTiO₃), as well as doped forms thereof (e.g., lanthanum doped strontium titanate). Other examples of perovskite oxides can include any that can be formed using precursors described herein. Yet other examples of perovskite oxides include those having any combination of alkali metals, alkaline metals, and transition metals described herein.

As described herein, hybrid molecular beam epitaxy (HMBE) can be used to grow perovskite oxide layers, while avoiding oxidizing conditions that can damage two-dimensional (2D) materials. For example, growth of SrTiO₃ on graphene is described, in which HMBE does not require independent oxygen source, thus avoiding graphene damage. Rather, HMBE uses a pre-oxidized metal precursor in combination with another metal precursor. This approach produces epitaxial films with self-regulating cation stoichiometry. More details regarding HMBE can be found in U.S. Provisional Application No. 63/452,109 filed on Mar. 14, 2023, which is hereby incorporated by reference. However, conventional MBE or other vacuum techniques can be used to grow the sacrificial layer and thin-films described herein.

Hybrid molecular beam epitaxy (HMBE) can be used to grow perovskite oxide layers, while avoiding oxidizing conditions that can damage 2D materials. For example, growth of SrTiO₃ on graphene using HMBE does not require an independent oxygen source, thus avoiding graphene damage. Rather, HMBE uses a pre-oxidized metal precursor in combination with another metal precursor. This approach produces epitaxial films with self-regulating cation stoichiometry. The growth substrate can include a van der Waals material, e.g., a material having out-of-plane van der Waals bonds and/or weak dangling bonds, disposed on a top surface of the substrate.

In some cases, the free-standing membrane (e.g., being about 50 nm thick), e.g., also referred to as a film, can be exfoliated and transferred to a secondary substrate (or a foreign substrate). Such methods can provide free-standing oxide nano-membranes grown in an adsorption-controlled manner by hybrid molecular beam epitaxy. In some cases, the film can be formed on a first substrate (e.g., a single crystal substrate, such as SrTiO₃ (001) or LSAT (001)), and then transferred to a secondary substrate (e.g., a flexible substrate, a dielectric substrate, a carrier substrate, etc.). This approach has potential implications for the commercial application of perovskite oxides in flexible electronics.

The film can be characterized in any useful manner. In some cases, the film comprises a single crystalline film. In some cases, the film comprises a nanomembrane (e.g., having a thickness from about 1 nm to about 1 micron). In some cases, the film is characterized by high mobility, high dielectric constant, high thermal conductivity, ferroelectricity, multiferroicity, and/or superconductivity. For example, the thin-film can be strontium titanate, which has an order of magnitude higher dielectric constant (¿=300), compared to conventional semiconductors (ε=30). Additionally, strontium titanate exhibits fair electricity when strained and superconductivity when chemically doped with rare earth elements.

### Formation of Freestanding Membrane

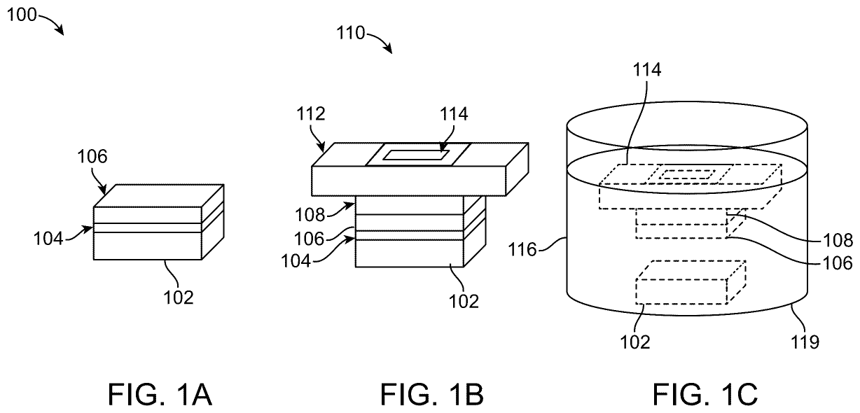

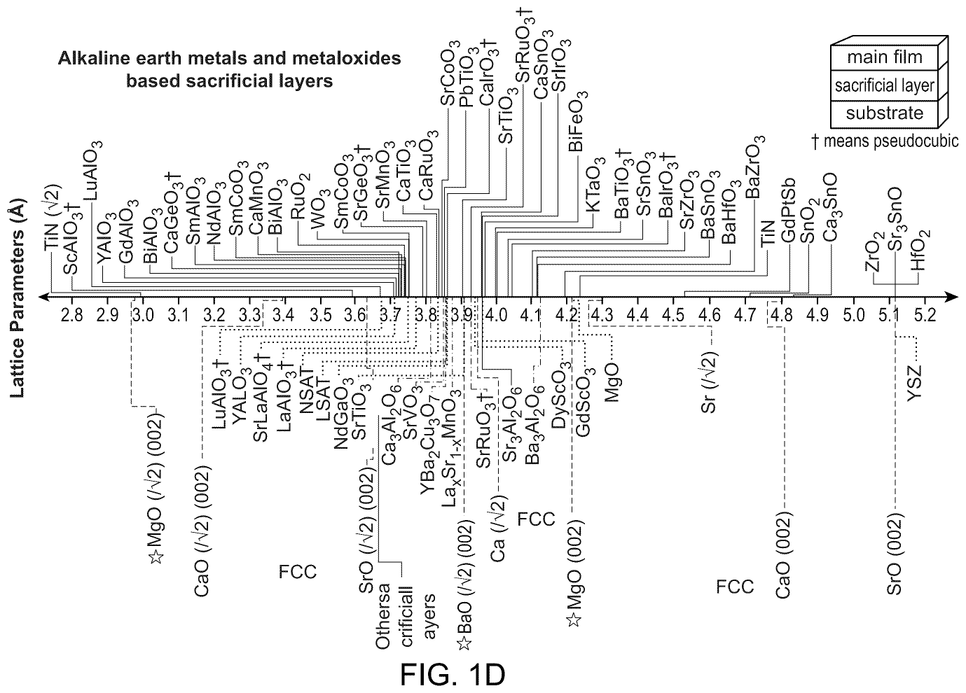

The present document encompasses methods of forming a free-standing membrane through use of a sacrificial layer. FIGS. 1A-1C provide a general overview of the method of releasing a thin-film from the substrate on which the thin-film was formed.

FIG. 1A depicts a stack 100 including a substrate 102, a sacrificial layer 104, and a thin-film 106. The sacrificial layer 104 and thin-film 106 can be grown on the substrate 102 using MBE or HMBE as described above.

The composition of the sacrificial layer 104 and the thin-film 106 can be selected individually and in combination to achieve desired properties of the thin-film 106. For example, the sacrificial layer 104 can include a combination of various alkaline earth metal oxides, e.g., SrO, MgO, CaO, and BaO, since SrO forms a solid solution with MgO, CaO, and BaO. The exact concentration of each type of alkaline earth metal oxide can be selected to tune a lattice parameter over a range of 2.98 Å to 5.16 Å. The tunability of the lattice parameter of the sacrificial layer 104 allows the sacrificial layer 104 to be grown on various substrates 102 and, importantly, enable various types of thin-films with differing lattice parameters to be grown on the sacrificial layer 104.

FIG. 1D depicts various options for the composition of the substrate 102, the sacrificial layer 104, and the thin-film 106, with lattice parameters plotted along a horizontal axis. For example, the substrate 102 can include LuAlO₃, YAlO₃, SrLaAlO₄, LaAlO₃, NSAT (e.g., (NdAlO₃)ₓ—(SrAl_{1/2}Ta_{1/2}O₃)₁₋ₓ, where x is 0.3 to 0.5), LSAT (LaAlO₃)ₓ—(SrAl_{1/2}Ta_{1/2}O₃)₁₋ₓ, where x is 0.2 to 0.4), NdGaO₃, SrTiO₃, DyScO₃, GdScO₃, MgO, and YSZ (yttria-stabilized zirconia), which span lattice parameters from about 3.7 Å to about 5.1 Å. The sacrificial layer 104 can include, e.g., CaO, SrO, BaO, MgO, Ca, and Sr, which span lattice parameters from about 3.0 Å to 5.1 Å (when rotated, see discussion below). The thin-film 106 can include, e.g., ScAlO₃, LuAlO₃, YAlO₃, GdAlO₃, BiAlO₃, CaGeO₃, SmAlO₃, NdAlO₃, NdAlO₃, SmCoO₃, CaMnO₃, BiAlO₃, RuO₂, WO₃, SmCoO₃, SrGeO₃, SrMnO₃, CaTiO₃, CaRuO₃, SrCoO₃, PbTiO₃, CaIrO₃, SrTiO₃, SrRuO₃, CaSnO₃, SrIrO₃, BiFcO₃, KTaO₃, BaTiO₃, SrSnO₃, BaIrO₃, SrZrO₃, BaSnO₃, BaHfO₃, BaZrO₃, TiN, GdPtSb, SnO₂, Ca₃SnO, ZrO₂, Sr₃SnO, and HfO₂, which span lattice parameters from about 3.6 Å to about 5.1 Å.

In some implementations, the lattice vectors of the sacrificial layer 104 are not parallel to the lattice vectors of at least one of the substrate 102 and thin-film 106. For example, all three of the substrate 102, sacrificial layer 104, and thin-film 106 can have cubic symmetry. The coordinate system of the sacrificial layer 104, however, can be rotated by 45° relative to the coordinate systems of the substrate 102 and the thin-film 106. The cations in the corners of each cubic cell can still form a cubic grid, but the lattice parameter of the rotated sacrificial layer 104 relative to the substrate 102 and thin-film 106 is divided by \sqrt{2}, e.g.,) sin (45°)=1/\sqrt{2}.

In some implementations, the sacrificial layer 104 can exhibit high thermal stability at high growth temperatures, e.g., 900° C. For example, an SrO sacrificial layer 104 can have low cation intermixing at the high growth temperatures often required for complex oxides during MBE. Additionally, SrO as a sacrificial layer can exhibit little to no thermal roughening. Other oxides (e.g., binary oxides) may be employed in the sacrificial layer.

In some non-limiting implementations, the sacrificial layer 104 does not include aluminum. The exclusion of aluminum and the sacrificial layer 104 can be advantageous because aluminum has a high reduction potential, e.g., −1.66 V. This high reduction potential can cause aluminum to oxidize, therefore becoming aluminum oxide. Additionally, aluminum can behave like a compensating impurity in semiconductor thin-films grown inside and MBE system.

In some implementations, the sacrificial layer 104 can be face-centered-cubic (FCC), e.g., have “rock salt” symmetry. In some implementations, either one of or both of the substrate 102 and thin-film 106 can be pseudo-cubic. The sacrificial layer 104 having high crystalline quality can encourage epitaxial growth in the thin-film 106.

The composition of the sacrificial layer 104 can encourage epitaxial growth in the thin-film 106, e.g., single crystalline growth as opposed to polycrystalline growth. For example, the entire thin-film 106 can have tetragonal, cubic, pseudo-cubic, orthorhombic, or trigonal symmetry. As a person of ordinary skill in the art will appreciate, the description “single crystalline” does not require a crystal to have 100% uniformity. For example, a single crystalline crystal can be of mainly one symmetry group, e.g., 70%, 80%, 90% or more.

In some implementations, polycrystalline or textured membranes can be desirable. Accordingly, these sorts of membranes can be grown using the disclosed techniques.

In some implementations, prior to etching the sacrificial layer, a supporting layer 108, e.g., a polymer support, can be applied to the stack 100, thereby forming a new stack 110, as depicted in FIG. 1B. A thermal release tape 112 can be attached to the supporting layer 108. A hole 114 in the thermal release tape 112 can extend through the entire thermal release tape 112, e.g., from a bottom surface contacting the supporting layer 108 to a top surface of the thermal release tape 112. The hole 114 allows a solution to contact the center of the stack 110 and can facilitate the removal of the thermal release tape 112 and adhering to another substrate after dissolution of the sacrificial layer 104.

The thermal release tape 112 can have a slightly larger surface area than the stack 100. Having a larger area than the stack 100 can make repositioning of the stack 110 easier than the positioning of the stack 100. For example, a mechanical arm can more easily pick up stack 110 compared to stack 100 given the larger surface area and rigid structure of the thermal release tape 112. Instead of a thermal release tape, other releasable components can be employed, such as a tape, layer, or other material that is releasable by chemical forces (e.g., solvation, dissolution, etc.), electromagnetic forces (e.g., ultraviolet irradiation), and/or physical forces (e.g., delamination).

FIG. 1C depicts etching the sacrificial layer 104 in the liquid 116 held by container 119. As the sacrificial layer 104 dissolves, the substrate 102 falls toward the bottom of the container 119, and the thin-film 106 attached to the supporting layer 108 and thermal release tape 112 remains floating. The thermal release tape 112 can be selected to have a density that is sufficiently low such that the buoyant force is strong enough for the thin-film 106, supporting layer 108, and thermal release tape 112 float rather than sink in the liquid 116.

The liquid 116 can include various liquids depending on the chemical composition of the stack 100. For example, when the sacrificial layer 104 is in alkaline earth metal oxide, the liquid 116 can be deionized water, as alkaline earth metal oxides dissolve in deionized water. As another example, the liquid can generally be non-acidic. For example, when the sacrificial layer 104 is MgO, the etching solution can be (NH₄)₂SO₄.

In some implementations, the temperature of the liquid 116 is controlled to facilitate etching of the sacrificial layer 104. For example, the temperature of deionized water when dissolving in alkaline earth metal oxide can be 60 to 70° C.

In some implementations, the etching of the sacrificial layer 104 can be relatively fast, e.g., 2-4 hours. This time span is relatively short compared to other methods of dissolving sacrificial layers, which can take up to over a day.

Although FIGS. 1B and 1C depict the stack 100 attached to the supporting layer 108 and thermal release tape 112, in some implementations, the stack 100 can be submerged in the liquid 116 without the supporting layer 108 and thermal release tape 112. When just the stack 100 itself is submerged in the liquid 116, the thin-film 106 is released from the substrate 102 and becomes a freestanding membrane. For example, the stack 100 can be placed upside down in the liquid 116, such that when the sacrificial layer 104 dissolves, a target substrate can be lowered into the liquid to contact the thin-film 106 and pick up the stack.

As an example, the sacrificial layer 104 can be SrO, and the thin-film 106 can be STO. In this example, no additional elemental sources are required during the growth process of STO after the growth process of SrO. As a result, installation of extra fusion cells inside and an MBE system can be avoided, which avoids costly installation of the extra fusion cells.

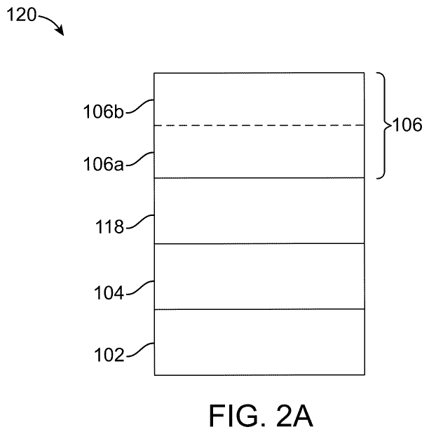

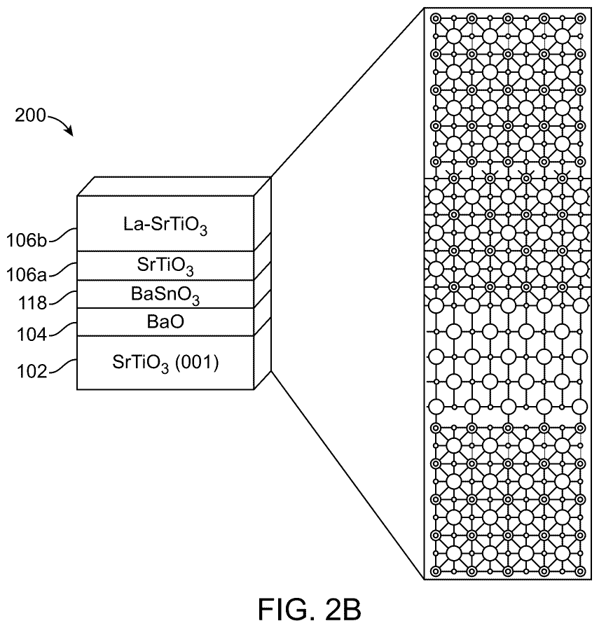

In some implementations, a barrier layer 118 is grown between the sacrificial layer 104 and the thin-film 106. FIG. 2A depicts a stack 120 including a barrier layer 118. For example, the stack 120 includes the substrate 102, the sacrificial layer 104, the barrier layer 118, and the thin-film 106. In some implementations, the barrier layer 118 is provided to avoid interfacial reactions, diffusion, or both between the sacrificial layer 104 and the thin-film 106. For example, when the sacrificial layer 104 is barium oxide (BaO) and the thin-film 106 is strontium titanate (STO), interfacial problems, e.g., oxygen dislocations, between STO and BaO can cause the STO to grow in a non-epitaxial manner, especially at temperatures required for MBE. However, the addition of a barrier layer 118, such as calcium stannate, can alleviate the interfacial problems. For example, calcium stannate grows epitaxially on BaO without interfacial problems, and STO can grow epitaxially on calcium stannate. FIG. 2B depicts a non-limiting stack 200 including a differing barrier layer 118 including barium stannate. The barrier layer can include other materials, e.g., an alkaline earth metal stannate such as XSnO₃, in which X is Ca or Ba. As another example, the barrier layer 118 can be a ruthenate, an iridate, or another material, e.g., SnO₂, Pt, SrRuO₃, SrIrO₃, or RuO₂, The barrier layer 118 is disposed above the sacrificial layer 104, which in this example is BaO on a substrate 102 composed of STO.

In some non-limiting implementations, the thin-film 106 can include two or more layers with different chemical compositions. For example, the thin-film 106 can include a first layer 106a and a second layer 106b. The first layer 106a can effectively be a substrate to synthesize the second layer 106b, which can be a broader range of materials than ABO₃ perovskites. For example, using an alkaline earth metal binary oxide as the sacrificial layer 104 allows for a relatively simple dissolution between the substrate 102 and the thin-film 106 and is generally compatible with growing ABO₃ perovskites as the thin-film 106. ABO₃ perovskites, while being useful thin-films themselves, can also be excellent substrates for growing other materials, such as other oxides and nitrides.

The layers of stacks 100 and 120 can have various dimensions. For example, the substrate 102 can have a height in a range of 0.2-1 mm, the sacrificial layer 104 can have a height in a range of 1-100 nm, e.g., about 5-8 nm, the barrier layer 118 can have a height of in a range of 2-100 nm, e.g., about 2 nm, the first layer 106a of the thin-film 106 can have a height in a range of 1-1000 nm, e.g., about 10 nm, and the second layer 106b of the thin-film 106 can have a height in a range of 100-1200 nm, e.g., about 360 nm. In some implementations, the height of the sacrificial layer 104 can be as small as one or more unit cells of the crystal making up the sacrificial layer 104, e.g., about 3 to 4 Å. In some implementations, the thin-film 106 (and stack 100 in general) can have lateral dimensions on the order of millimeters.

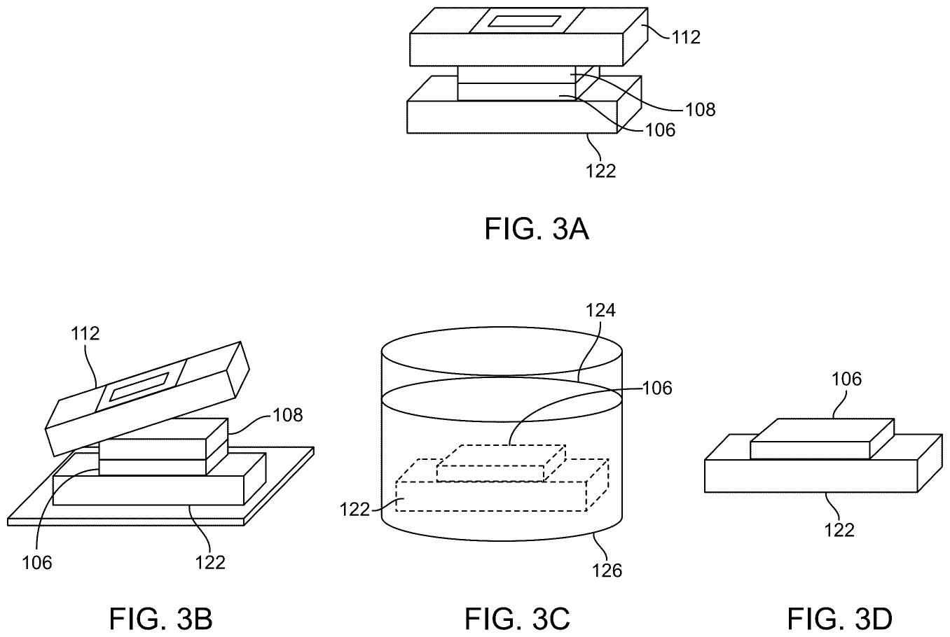

FIGS. 3A-3D depict schematics of the process of transferring the thin-film 106 to a host substrate 122 and removing the supporting layer 108 and thermal release tape 112. FIG. 3A depicts the thin-film 106, which has been removed from the container 119 along with the supporting layer 108 and thermal release tape 112 still attached to the thin-film 106. The thin-film 106 is adhered to the host substrate 122. For example, a mechanical arm supporting the host substrate 122 can scoop the stack out of the container 119. The same side of the thin-film 106 that was in contact with the sacrificial layer 104 is the side that adheres to the host substrate 122.

The host substrate 122 can include any useful structure (e.g., a heterostructure) or material (e.g., oxide, dielectric, conductor, polymer, or a combination thereof). In some cases, the host substrate 122 is a flexible substrate or a carrier substrate. In some implementations, the host substrate 122 is Au-coated silicon.

Non-limiting materials for the supporting layer 108 include a polymer, an epoxy, a photoresist, a substrate, or a combination of any of these. Optionally, the supporting layer 108 can be attached by use of an adhesion layer, which can include an adhesive, a tape, a polymer, a photoresist, and the like, e.g., polydimethylsiloxane (PDMS).

In FIG. 3B, heat is applied to the host substrate 122 which transfers to thermal release tape 112, thereby causing the thermal release tape 112 to detach from the supporting layer 108. For example, a hot plate can apply the heat to the host substrate 112.

When an adhesion layer between the thin-film 106 and the host substrate 122 is present, removal of the adhesion layer and/or support layers 108 can include wet processes, dry processes, or a combination thereof (e.g., etching, peeling, heating, solubilizing, or a combination of any of these). When an adhesion layer is present, removal of the adhesion layer can result in detachment, and thus removal, of the supporting layer 108.

In FIG. 3C, the host substrate 122, which is supporting the thin-film 106 and the supporting layer 108, is immersed in another liquid 124 held by a container 126. The liquid 124 etches or otherwise removes (e.g., by dissolution, solvation, etc.) the supporting layer 108 off of the thin-film 106. For example, the liquid 124 can be acetone. In addition to wet processes, dry processes may be employed to remove the supporting layer 108 (e.g., by use of electromagnetic radiation, dry etching, and the like).

In FIG. 3D, the host substrate 122, now only supporting the thin-film 106, is removed from the container 126. At this stage, the thin-film 106 supported by host substrate 122 can be ready for use in a variety of applications. For example, the host substrate 122 can be a glass or amorphous slide, which would make the thin-film 106 useful for application in the complementary metal oxide semiconductor (CMOS) industry.

In some cases, the thin-film 106 (after exfoliation and/or transfer) can retain the structural properties that are determined after deposition of the material. That is, in some cases, the steps of exfoliation and transfer do not damage the thin-film material, e.g., a perovskite.

The thin-film 106 can be further treated. In some cases, the thin-film 106 can be annealed (e.g., in the presence of oxygen, hydrogen, an inert gas, vacuum, high pressure, or a combination of any of these), doped, plasma treated, oxidized, coated, or a combination of any of these.

### Methods

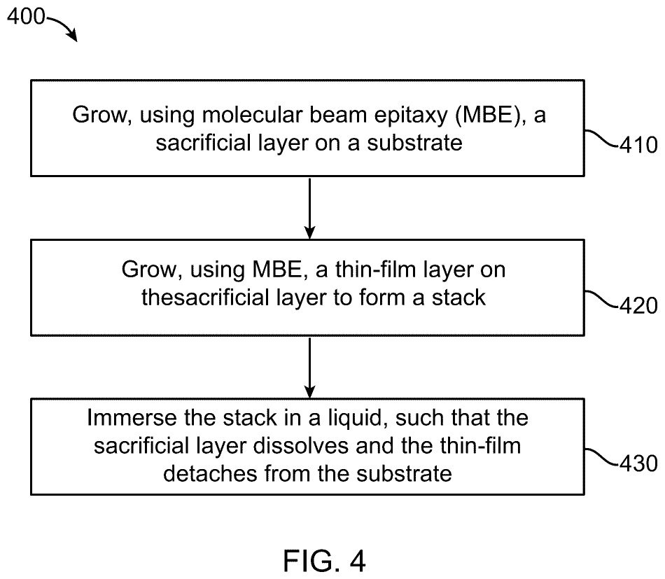

FIG. 4 depicts a method 400 of forming a freestanding membrane.

The method 400 begins with growing, using molecular beam epitaxy (MBE), a sacrificial layer, e.g., sacrificial layer 104, on the substrate 102 (410). In some implementations, MBE includes hybrid MBE. Although the method 400 describes an example using MBE, other vacuum techniques can be used. As used herein, the term MBE can also include hybrid MBE.

The method 400 continues with growing, using MBE, a thin-film, e.g., thin-film 106, on the sacrificial layer to form a stack, e.g., stack 100 (420). The thin-film can include one or more layers of different chemical composition.

The method 400 continues with immersing the stack in the liquid, e.g., liquid 116, such that the sacrificial layer dissolves and the thin-film detaches from the substrate (430). By detaching from the substrate, the thin-film becomes a freestanding membrane, which can be stretchable. The process of detaching the thin-film 106 from the substrate 102 can be referred to as exfoliation.

In some implementations, the freestanding membrane can exhibit responses similar to the bulk version of the crystal, e.g., the piezoelectric response of a thin-film of STO can be as great as the piezoelectric response of bulk STO.

In some implementations, the method 400 can include additional steps or some of the steps can be divided into multiple steps. For example, the method 400 can include, before step 410, growing the substrate 102 using a variety of methods.

In some implementations, between steps 410 and 420, the method 400 includes growing the barrier layer on the sacrificial layer, the barrier layer having a chemical composition different from both the sacrificial layer and the thin-film.

In some implementations, between steps 420 and 430, a supporting layer 108, such as a polymer, and thermal release tape 112 can be attached to the thin-film 106. When the thin-film 106 is attached to the supporting layer 108 and the thermal release tape 112, the method 400 can at least one of the following two steps. First, the method can include removing the thermal release tape 112 by applying heat to the host substrate 122 to cause the thermal release tape 112 to detach from the supporting layer 108 and etching the supporting layer 108. Second, the method can include etching the supporting layer in etching liquid to expose a surface of the thin-film 106.

In some implementations, after step 430, the method includes transferring the thin-film 106 to a host substrate, e.g., host substrate 122.

In some implementations, the temperature of each step in method 400 is controlled. For example, the temperatures during MBE growth in steps 410 and 420 can be in a range of 400-1000° C. In general, the temperature ranges during MBE growth are higher than those of pulsed laser deposition (PLD), which can make achieving epitaxial growth difficult. For example, although a stack without a barrier layer might grow epitaxially using PLD, e.g., STO on BaO, the absence of a barrier layer can lead to non-epitaxial growth in MBE. For example, titanium from the STO can diffuse into the BaO layer and perturb the epitaxial growth of STO. For example, steps 410 and 420 can be performed in a temperature range of 600-1000° C., e.g., 900° C., while typical PLD process takes place within a range of 600-800° C. . . .

In some implementations, after a particular thin-film has detached from a substrate, e.g., substrate 102, the substrate 102 can be reused for growing another round of the sacrificial layer 104 and thin-film 106.

### Applications

As described above, the present techniques can be applied to various applications. To name just a few examples, the stretchable thin-film supported by a host substrate can be used in applications that involve extreme strain engineering on the host substrate. The thin-film can also be applied to flexible substrates, e.g., foldable electronics, for various uses.

In some implementations, multiple thin-film membranes can be stacked upon one another to form three-dimensional (3D) architectures to achieve desired physical properties, e.g. piezoelectric and ferroelectric responses. As an example, stacked membranes can include symmetry-mismatch heterostructures.

In some implementations, the thin-films can be used in Half-Huesler alloys, e.g., magnetic, topological materials with lattice parameters of 3.5 Å or lower.

### Experimental Results

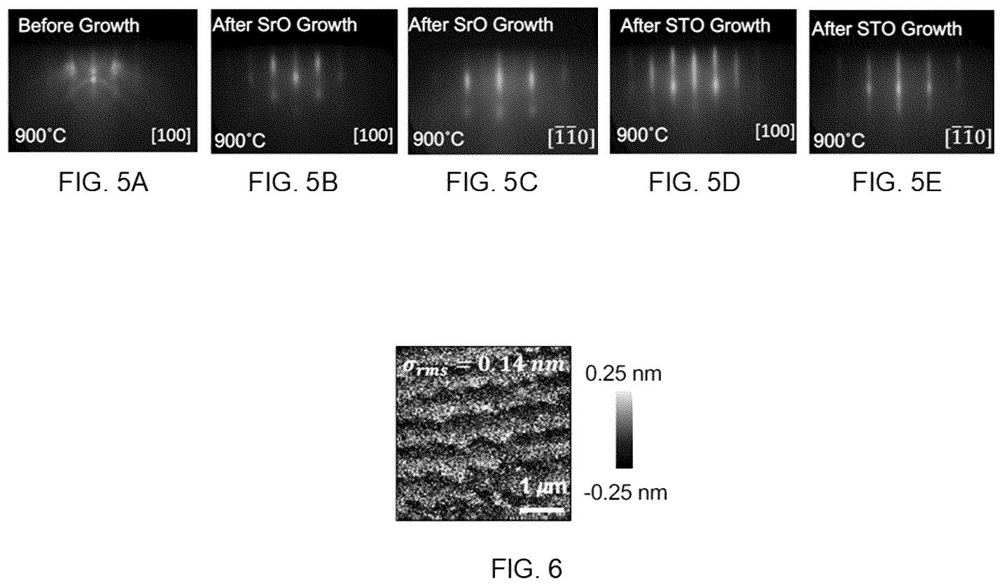

FIGS. 5A-5E and 6 show experimental results of applying the disclosed techniques to a stack including a LaAlO₃ substrate, a SrO sacrificial layer, and a SrTiO₃ thin-film. In this example, a sacrificial layer of about 5 nm of SrO is grown on the LaAlO₃ substrate, and a thin-film of about 10 nm of STO is grown on the sacrificial layer. The clear reflection high-energy electron diffraction (RHEED) oscillations (FIGS. 5A-5E) show that this technique results in atomic precision. FIG. 6 depicts an atomically smooth surface of the STO thin-film visible from atomic force microscopy. As depicted in the color bar, the termination surface ranges±0.25 nm around an average height, with a standard deviation of the root mean square of 0.14 nm.

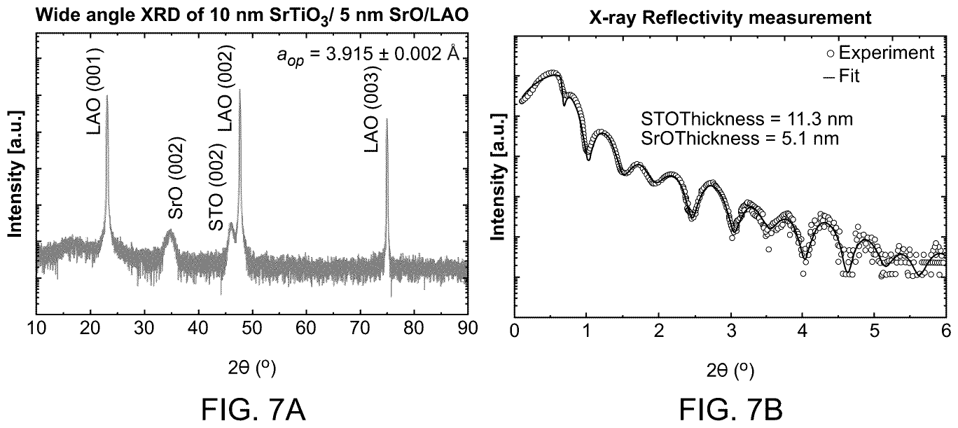

FIG. 7A depicts wide-angle x-ray diffraction (XRD) results for the present example. FIG. 7A shows that the lattice parameters for the LAO substrate, sacrificial layer SrO and the thin-film STO agree with predicted values for these lattice parameters. These results indicate that the disclosed technique of growing the thin-film on a sacrificial layer achieves excellent structural quality and reproducibility.

FIG. 7B depicts x-ray reflectivity measurement in the present example. The thicknesses of each of the sacrificial and thin-films can be extracted from the reflectivity of surfaces and interfaces of the stack based on the density and surface roughness of each layer of the stock, and the experimental results agree well with the predicted results. For example, the thickness of the STO thin-film is 11.3 nm, and the thickness of the SrO sacrificial layer is 5.1 nm.

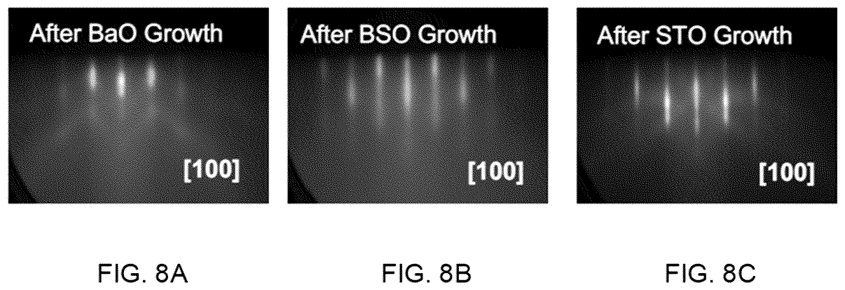

As another example, FIGS. 8A-8C show the results of applying the disclosed techniques to a stack including a barrier layer and two thin-films, e.g., stack 120. As an example, stack 120 can include the following composition. The substrate 102 can be STO, e.g., bulk, tetragonal STO, the sacrificial layer 104 can be about 8 nm of BaO, the barrier layer 118 can be about 2 nm of BaSnO₃, the first layer 106a of the thin-film 106 can be about 10 nm of STO, and the second layer 106b of the thin-film 106 can be about 360 nm of La-STO, e.g., La-doped STO. Consistent with the findings in FIGS. 5A-5E, the RHEED oscillations show that the disclosed technique, e.g., growing thin films on a barrier layer on a sacrificial layer, results in atomic precision.

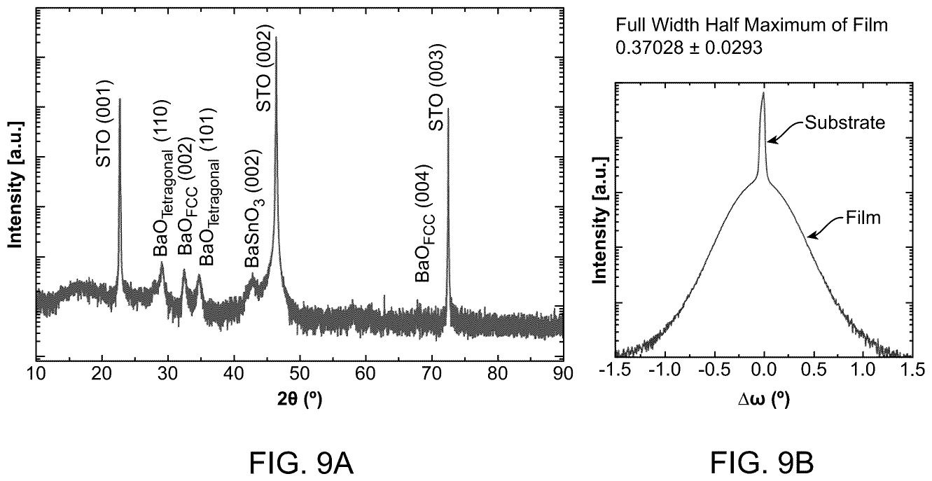

FIG. 9A depicts wide-angle x-ray diffraction (XRD) results for the present example. FIG. 9A shows that the lattice parameters for the sacrificial layer BaO, the barrier layer BSO, and the thin-film STO agree with predicted values for these lattice parameters. These results indicate that this technique, e.g., growing thin films on a barrier layer on a sacrificial layer, achieves excellent structural quality and reproducibility.

To investigate the structural quality of the film, rocking curve scans were performed of the SrTiO₃ (002) peak, as depicted in FIG. 9B. The rocking curve of the film and the substrate overlap, yielding a narrow rocking curve (FWHM=0.037°).

As another example, a stack can include a LSAT (001) substrate, a SrO sacrificial layer, and a BaTiO₃ thin-film. In this example, a sacrificial layer of about 10 nm of SrO can be grown on the LSAT substrate, and a thin-film of about 60 nm of BaTiO₃ can be grown on the sacrificial layer. In some cases, the BaTiO₃ thin-film can be grown under various titanium isopropoxide (TTIP)/Ba flux ratios.

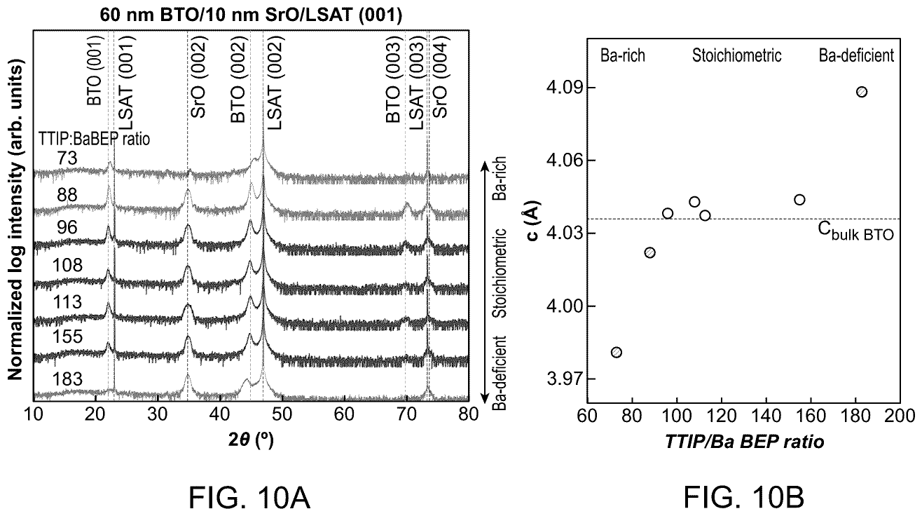

FIG. 10A depicts XRD plots for this example, which exhibited various peaks for the BaTiO₃ layer, the LSAT layer, and the SrO layer. The BaTiO₃ (001) series peaks in the XRD confirmed the epitaxial growth of the BaTiO₃ thin-film on the SrO sacrificial layer. Depending on the TTIP/Ba flux ratios, the results were Ba-deficient, stoichiometric, or Ba-rich.

FIG. 10B shows the extracted lattice parameters of the SrO sacrificial layer and BaTiO₃ thin-film, according to some embodiments. The out-of-plane lattice parameters of the BaTiO₃ films were extracted using the BaTiO₃ (002) peaks from FIG. 10A. The out-of-plane lattice parameters of the BaTiO₃ films with various TTIP/Ba flux ratios were close to the bulk-like value when the ratio was in the range of 100 to 160, indicating adsorption-controlled growth.

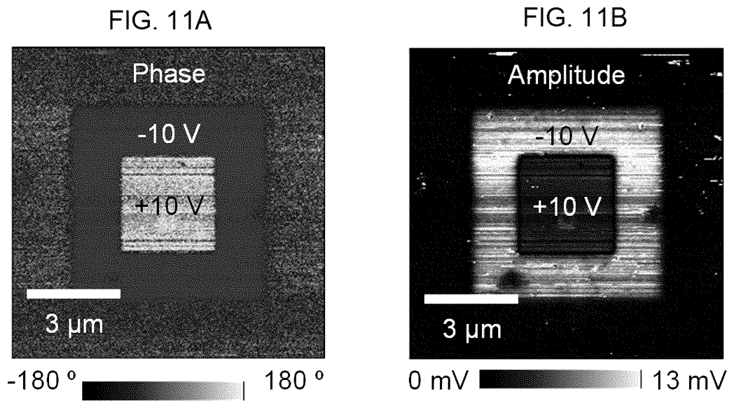

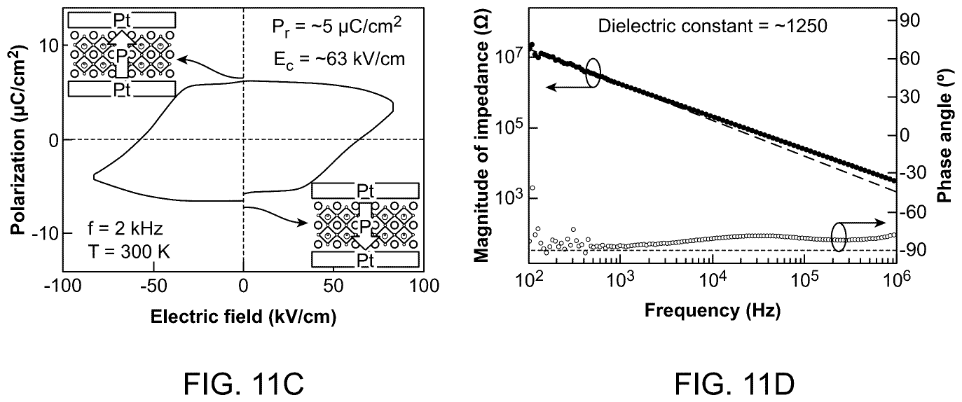

FIGS. 11A and 11B depict piezoresponse force microscopy (PFM) images for a freestanding nm BaTiO₃ membrane. The BaTiO₃ membrane was 20 nm thick and transferred onto an Au-coated Si substrate. To pole the BaTiO₃ membrane, a DC bias of −10 V was applied to 6 μm×6 μm region centered on the substrate, and a DC bias +10 V was 3 μm×3 μm region centered on the substrate. Subsequently, a 10 μm×10 μm out-of-plane PFM image was obtained. FIG. 11A shows that the central 3 μm×3 μm region had positive phase angle, and the 6 μm×6 μm region surrounding the 3 μm×3 μm region had negative phase angle. FIG. 11B shows the 6 μm×6 μm region surrounding the 3 μm×3 μm region had nonzero amplitude response, indicating a nonzero piezoelectric tensor. These results indicate that polarization was retained after the poling process, confirming its ferroelectricity.

FIG. 11C depicts a polarization-electric field hysteresis loop of a BaTiO₃ device (Pt/BaTiO₃ membrane/Pt), measured by using a positive-up-negative-down (PUND) method. The BaTiO₃ device exhibited a remnant polarization of ˜5 μC/cm² (the −Y axis intercept) and a coercive field of ˜63 kV/cm (the −X axis intercept) under a frequency of 2 kHz at room temperature, demonstrating the ferroelectricity of the BaTiO₃ membrane.

The dielectric constant of the BaTiO₃ membrane can be calculated based on the impedance measurement. Using a linear fit of the measured magnitude of the impedance in the frequency range of 100 Hz to 1 kHz, where the phase angle is close to −90°, the dielectric constant was about 1250.

### OTHER EMBODIMENTS

It is to be understood that while the invention has been described in conjunction with the detailed description thereof, the foregoing description is intended to illustrate and not limit the scope of the invention, which is defined by the scope of the appended claims. Other aspects, advantages, and modifications are within the scope of the following claims.

What is claimed is:

1. A method of forming a perovskite oxide, the method comprising:
growing, using molecular beam epitaxy (MBE), a sacrificial layer on a substrate;
growing, using MBE, a thin-film on the sacrificial layer to form a stack; and
removing the sacrificial layer to detach the thin-film from the stack.

2. The method of claim 1, further comprising, after said removing, transferring the thin-film to a host substrate.

3. The method of claim 1, further comprising, before said removing, attaching the thin-film to a supporting layer.

4. The method of claim 3, wherein the supporting layer is attached to a thermal release tape.

5. The method of claim 3, further comprising removing the supporting layer to expose the thin-film.

6. The method of claim 1, further comprising, before said growing the thin-film, growing a barrier layer, the barrier layer having a different chemical composition compared to the sacrificial layer and the thin-film.

7. The method of claim 6, wherein the barrier layer comprises an alkaline earth metal stannate.

8. The method of claim 1, wherein the thin-film comprises an ABO₃ perovskite.

9. The method of claim 1, wherein the thin-film comprises SrTiO₃, and the sacrificial layer comprises SrO.

10. A stack comprising:
a substrate having a top surface and a bottom surface;
a sacrificial layer disposed on at least a portion of the top surface of the substrate; and
a barrier layer disposed on at least a portion of a top surface of the sacrificial layer,
wherein each of the substrate, the sacrificial layer, and the barrier layer comprises cubic symmetry, and
wherein the barrier layer comprises an alkaline earth metal stannate.

11. The stack of claim 10, wherein the substrate comprises Si, LuAlO₃, YAlO₃, SrLaAlO₄, LaAlO₃, NSAT (e.g., (NdAlO₃)ₓ—(SrAl_{1/2}Ta_{1/2}O₃)₁₋ₓ, where x is 0.3 to 0.5), LSAT (LaAlO₃)ₓ—(SrAl_{1/2}Ta_{1/2}O₃)₁₋ₓ, where x is 0.2 to 0.4), NdGaO₃, SrTiO₃, DyScO₃, GdScO₃, MgO, or YSZ (yttria-stabilized zirconia).

12. The stack of claim 10, wherein the sacrificial layer comprises CaO, SrO, BaO, MgO, Ca, Sr, or a combination of any of these.

13. The stack of claim 10, wherein the barrier layer comprises SnO₂, Pt, a ruthenate, an iridate, or XSnO₃, in which X is Be, Mg, Ca, Ba, Sr, Ra, or a combination of any of these.

14. The stack of claim 10, further comprising:
a thin-film disposed on at least a portion of a top surface of the barrier layer.

15. The stack of claim 12, wherein the thin-film comprises an ABO₃ perovskite or a doped form thereof.

16. The stack of claim 14, wherein the thin-film comprises one or more layers, at least one layer of the one or more layers comprising a binary oxide.

17. The stack of claim 14, wherein the thin-film is piezoelectric.

18. The stack of claim 14, wherein the thin-film is ferroelectric.

19. The stack of claim 14, wherein the thin-film comprises ScAlO₃, LuAlO₃, YAlO₃, GdAlO₃, BiAlO₃, CaGeO₃, SmAlO₃, NdAlO₃, NdAlO₃, SmCoO₃, CaMnO₃, BiAlO₃, RuO₂, WO₃, SmCoO₃, SrGeO₃, SrMnO₃, CaTiO₃, CaRuO₃, SrCoO₃, PbTiO₃, CaIrO₃, SrTiO₃, SrRuO₃, CaSnO₃, SrIrO₃, BiFeO₃, KTaO₃, BaTiO₃, SrSnO₃, BaIrO₃, SrZrO₃, BaSnO₃, BaHfO₃, BaZrO₃, TiN, GdPtSb, SnO₂, Ca₃SnO, ZrO₂, Sr₃SnO, HfO₂, or a combination of any of these.

20. The stack of claim 10, wherein a lattice parameter of the sacrificial layer is in a range of 3.6 Å to about 5.1 Å.
